(19) United States
(12) Patent Application Publication
(10) Pub. No.: US 2008/0197903 A1
(43) Pub. Date: Aug. 21, 2008

(54) Clock Pulse Duty Cycle Control Circuit for a Clock Fanout Chip

(75) Inventor: James S. Humble, Rochester, MN (US)

Correspondence Address: FAEGRE & BENSON;ATTN: PATENT DOCKETING, 2200 WELLS FARGO CENTER, 90 SOUTH SEVENTH STREET, MINNEAPOLIS, MN, 55402-3901, US

(73) Assignee: Mayo Foundation for Medical Education and Research, Rochester, MN (US)

(21) Appl. No.: 11/813,844

(22) PCT Filed: Jan. 13, 2006
(86) PCT No.: PCT/US2006/001340

§ 371 Date: May 1, 2008

Related U.S. Application Data
(60) Provisional application No. 60/643,926, filed on Jan. 14, 2005.

(51) Int. Cl. H03K 3/017

(52) U.S. Cl. 327/175

(57) ABSTRACT

A clock pulse duty cycle control circuit for receiving an input clock signal and for providing an output clock signal having a desired duty cycle. An error signal generator includes a differential integrator that is connected to receive the output clock signal. The differential integrator integrates the output clock signal to produce a time-varying DC error signal representative of a difference between the output clock signal duty cycle and the desired duty cycle. A duty cycle corrector includes a differential integrator connected to receive the input clock signal and the error signal. The differential integrator integrates the input clock signa to produce a correction stage clock signal. The differential integrator causes the slopes of the input clock signal edges to be adjusted as a function of the error signal. A buffer including a high gain amplifier is connected to receive the correction stage clock signal and squares the edges of the clock signal to produce the output clock signal.

### GOVERNMENT LICENSE RIGHTS

The invention was made with funding support provided by the U.S. government. The U.S. government may have certain rights to the invention.

### FIELD OF THE INVENTION

The invention relates generally to electronic circuits for generating digital clock signals. In particular, the invention is a circuit for adjusting the pulse duty cycle of clock signals.

### BACKGROUND OF THE INVENTION

Clock data/driver circuits are generally known and commercially available. One such clock/data driver is the NBSG111 available from ON Semiconductor. This clock/data driver includes a fanout or tree structure that provides many different but synchronized clock signal outputs. Unfortunately, the clock signals produced by drivers of these types can have duty cycle deviations that are unacceptable for certain applications.

Circuits for correcting the duty cycles of clock signals are generally known. One such circuit is disclosed in the publication S. Karthikeyan, “Clock Duty Cycle Adjuster Circuit For Switched Capaciter Circuits,” Electronics Letters, PP 1008-1009, Aug. 29, 2002.

There remains, however, a continuing need for improved clock signal duty cycle control circuits. In particular, there is a need for accurate and high-speed duty cycle control circuits that can be efficiently implemented in integrated circuit form. A duty cycle adjuster circuit of this type that is capable of robust operation over a range of clock frequencies, and that enables the selection of several different duty cycles, would be especially desirable.

### SUMMARY OF THE INVENTION

The present invention is a high-speed and efficient-to-implement clock signal duty cycle control circuit. The circuit can be configured to accurately operate over a range of clock frequencies and to enable the selection of several different duty cycles.

One embodiment of the invention includes an error signal generator, a duty cycle corrector and a buffer. The error signal generator is connected to receive an output clock signal, and produces an error signal representative of a difference between the output clock signal duty cycle and a desired duty cycle. The duty cycle corrector is connected to receive the error signal and an input clock signal, and adjusts slopes of the input clock signal edges as a function of the error signal to produce a correction stage clock signal. The buffer is connected to receive the correction stage clock signal, and squares the edges of the clock signal to produce the output clock signal.

Another embodiment of the invention is a two-stage circuit having second duty cycle correctors and buffers. Digital control signals coupled to the error signal generator can be used to select the desired duty cycle of the clock signal. Digital control signals connected to the duty cycle corrector can be used to select bias currents to scale the loop gain of the circuit to different clock signal frequencies.

### BRIEF DESCRIPTION OF THE DRAWINGS

FIG. 1 is a functional block diagram of a clock fanout chip including a duty cycle control circuit in accordance with the present invention.

FIG. 2 is a block diagram of the duty cycle control circuit shown in FIG. 1.

FIG. 3 is an illustration of a clock signal at the input and output of each of the functional blocks of the duty cycle control circuit shown in FIG. 2.

FIG. 4 is a functional schematic diagram of the error signal generator shown in FIG. 2.

FIG. 5 is a graph of the error signal, produced by the error signal generator shown in FIG. 4, as a function of the duty cycle of the output clock signal.

FIG. 6 is a graph of a 70/30 duty cycle input clock signal, a corrected 50/50 duty cycle output clock signal and a corresponding error signal on a common time scale.

FIG. 7 is a detailed schematic diagram of a circuit implementation of the error signal generator shown in FIG. 4.

FIG. 8 is a functional schematic diagram of the duty cycle corrector shown in FIG. 2.

FIG. 9 is a detailed schematic diagram of a circuit implementation of the duty cycle corrector shown in FIG. 8.

FIG. 10 is a detailed schematic diagram of a circuit implementation of the buffer shown in FIG. 2.

### DETAILED DESCRIPTION OF THE PREFERRED EMBODIMENTS

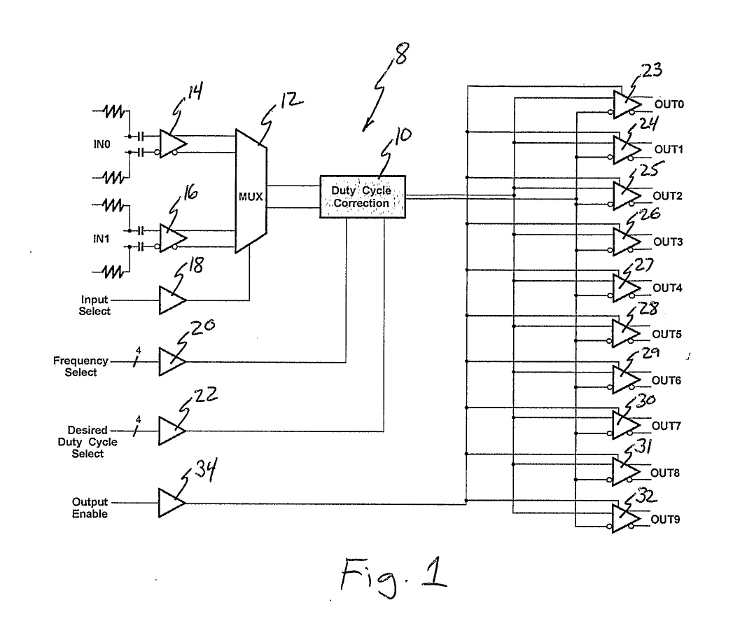

FIG. 1 is a block diagram of a double-ended 1:10 fanout clock/data driver 8 that includes a duty cycle correction circuit 10 in accordance with the present invention. As shown, a pair of clock signals IN0 and IN1 are applied to a multiplexer (MUX) 12 through input buffers 14 and 16, respectively. The clock signals IN0 and IN1 are coupled to the input buffers 14 and 16, respectively, though coupling capacitors and resistive dividers. An Input Select signal is applied to the multiplexer 12 through buffer 18. In response to the Input Select signal, the multiplexer 12 will select one of the clock signals IN0 and IN1 for application to the duty cycle correction circuit 10.

In the embodiment illustrated and described in detail below, duty cycle correction circuit 10 is connected to receive a 4-bit Frequency Select signal and a 4-bit Desired Duty Cycle Select signal in addition to the clock signal. The Frequency Select and Desired Duty Cycle Select signals are applied to the duty cycle correction circuit 10 through buffers 20 and 22, respectively. Duty cycle correction circuit 10 operates to control or adjust the duty cycle of the input clock signal. Specifically, duty cycle correction circuit 10 produces an output clock signal having a duty cycle that is locked to the duty cycle requested by the Desired Duty Cycle Select signal. The clock signal outputted by the duty cycle correction circuit 10 is then applied to each of ten output buffers 23-32 that provide output clock signals OUT0-OUT9, respectively. Output buffers 23-32 are driven between active and inactive states by an Output Enable signal that is applied to each of the buffers through buffer 34.

FIG. 2 is a block diagram of one embodiment of the duty cycle correction circuit 10. As shown, the circuit 10 includes an error signal generator 40, first duty cycle corrector 42, first buffer 44, second duty cycle corrector 46 and second buffer 48 connected in a negative feedback loop. Error signal generator 40 has input terminals PIN and MIN connected to receive the clock signal outputted from second buffer 44 at terminals POUT and MOUT, and input terminal SELECT connected to receive the Desired Duty Cycle Select signal. In the embodiment described herein, the Desired Duty Cycle Select signal is a 4-bit digital signal representative of a desired duty cycle. Error signal generator 40 produces an error signal that is representative of the difference between the duty cycle of the (actual) output signal received at the input terminals PIN and MIN and the desired duty cycle represented by the Desired Duty Cycle Select signal received at the SELECT terminal. The error signal is outputted from the error signal generator 40 at terminals PCORRECT and MCORRECT. As described in greater detail below, the error signal is a pseudo-DC signal having a magnitude representative of the difference between the actual and desired duty cycles of the clock signal.

The duty cycle error signal is applied to the input terminals PCORRECT and MCORRECT of both duty cycle correctors 42 and 46. The output terminals POUT and MOUT of both duty cycle correctors 42 and 46 are connected to the input terminals PIN and MIN of buffers 44 and 48, respectively. Duty cycle correctors 42 and 46 operate in a similar manner, and slow the edges of the clock signal pulses as a function of the error signal. Buffers 44 and 48 also operate in a similar manner, and square the clock pulse edges. The result of these operations is a clock signal outputted from buffer 44 having pulse duty cycles equal to those selected by the Desired Duty Cycle Select signal. Although the embodiment shown in FIG. 2 is a two-stage device (i.e., it has two duty cycle correctors and two buffers), other embodiments of the invention (not shown) have more or fewer stages.

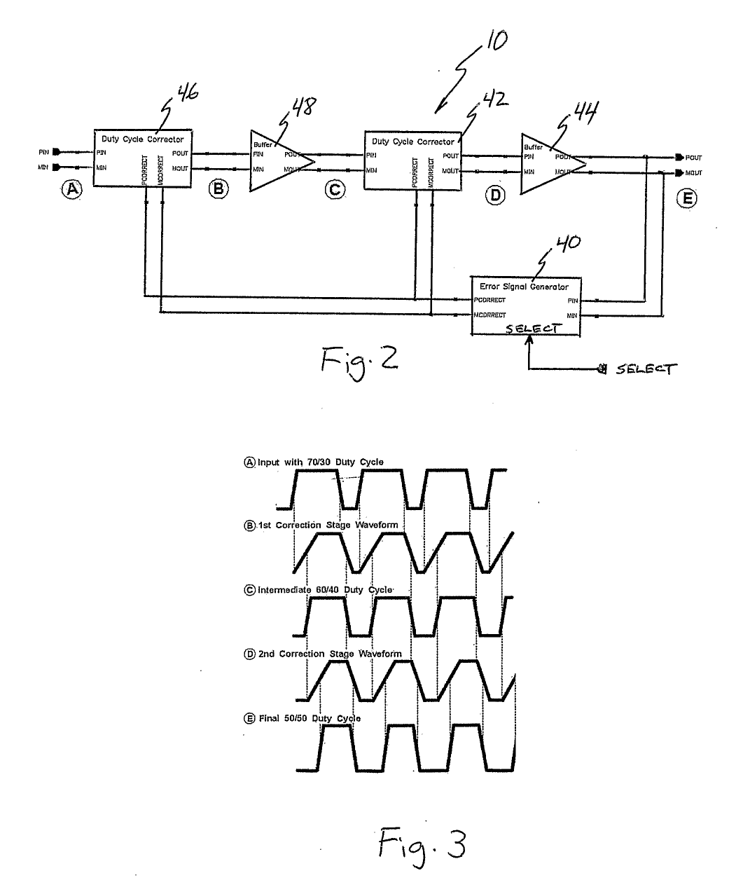

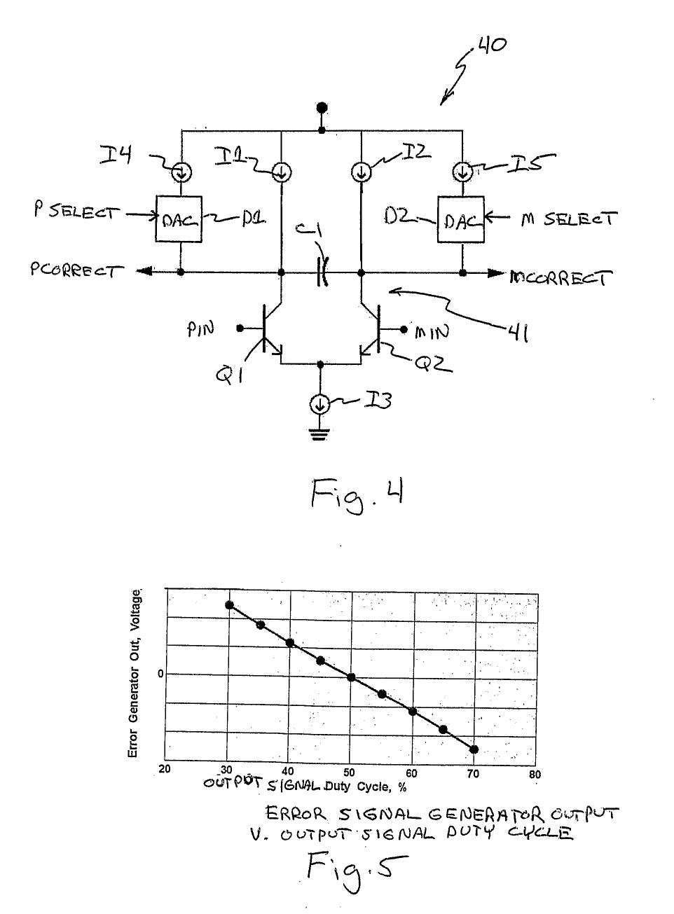

The operation of the duty cycle correction circuit 10 shown in FIG. 2 can be described in connection with the example clock signals shown in FIG. 3. This example is based upon the error signal generator operating in response to a Desired Duty Cycle Select signal representative of a 50% (i.e., 50/50) duty cycle. In this example, the clock signal A inputted to duty cycle corrector 46 has a 70/30 duty cycle. Duty cycle corrector 46 slows the edges of the clock signal A by an amount proportional to the error signal, and produces a correction stage clock signal B. As shown in FIG. 3, the correction stage clock signal B has its rising edges slowed by an amount greater than the amount that the falling edges are slowed. Buffer 48 squares the edges of the correction stage clock signal B, and produces an intermediate corrected clock signal C. In this example the intermediate corrected clock signal C has a 60/40 duty cycle. In a similar manner, the duty cycle corrector 42 slows the edges of the intermediate corrected clock signal C and produces a correction stage clock signal D. As shown in FIG. 3, the correction stage clock signal D has its rising edges slowed by an amount greater than the amount that the falling edges are slowed. Buffer 44 squares the edges of the correction stage clock signal D to produce the output clock signal E. In this example the duty cycle corrector 42 and buffer 44 complete the duty cycle correction function and cause the output clock signal E to have the 50/50 duty cycle specified by the Desired Duty Cycle Select signal.

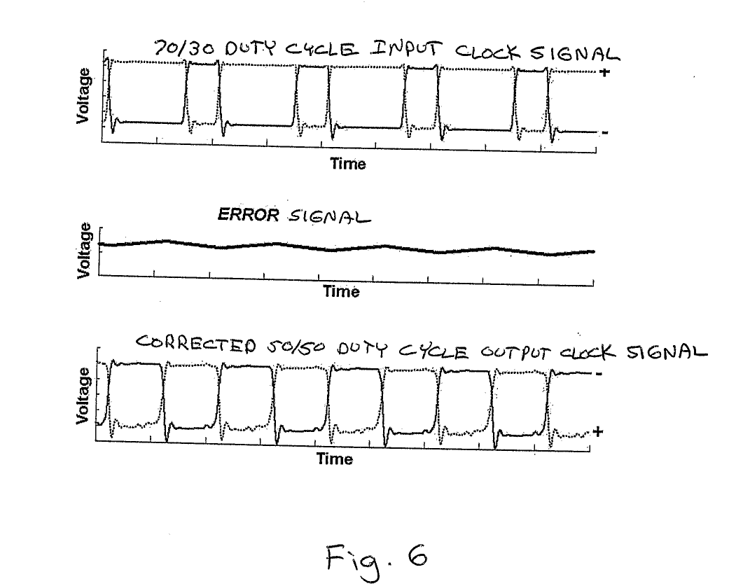

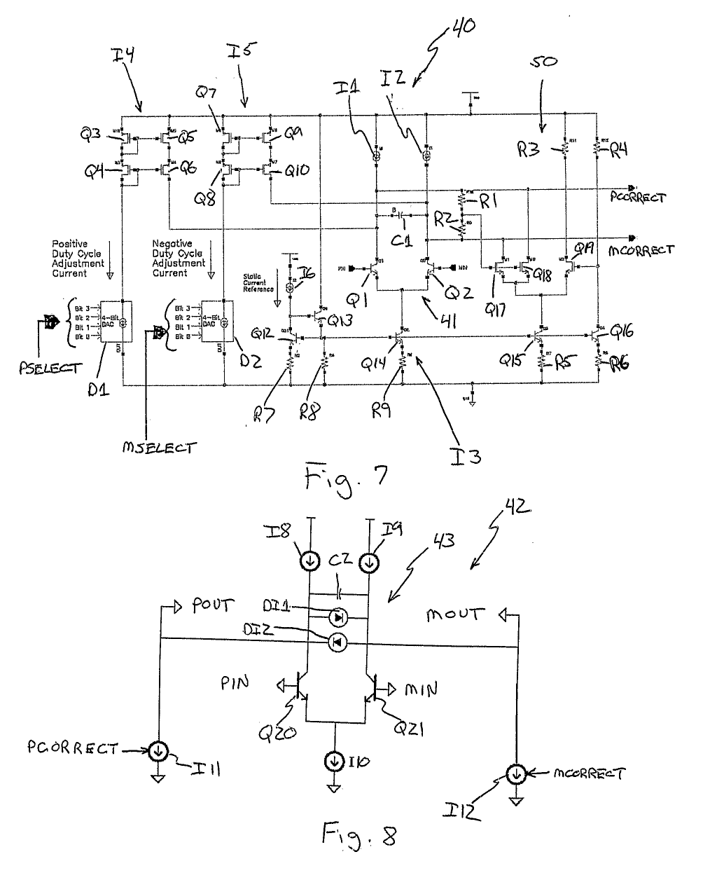

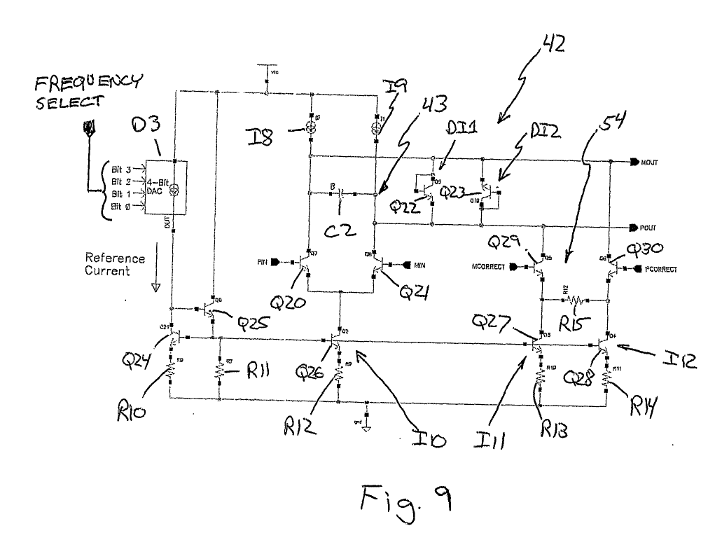

FIG. 4 is a functional schematic diagram of the error signal generator 40 shown in FIG. 3. The error signal generator 40 is a differential change pump and includes a differential integrator 41 formed by transistors Q1 and Q2 and capacitor C1 connected to current sources 11-15 and digital-to-analog converters (DACs) D1 and D2. Current sources I1 and 12 provide fixed and equal currents. The amount of current coupled to the capacitor C1 from current sources I4 and I5 is controlled by DACs D1 and D2, in response to the Desired Duty Cycle Select signal applied to terminals PSELECT and MSELECT. In response to Desired Duty Cycle Select signals representative of a 50/50 duty cycle, DACs D1 and D2 will cause equal amounts of current to be supplied from current sources 14 and 15. When the Desired Duty Cycle Select signals are representative of duty cycles other that 50/50, DACs D1 and D2 will cause different amounts of current to be supplied from current sources 14 and I5 (a differential reference current), with the differential being proportional to the difference between the desired duty cycle and a 50/50 duty cycle.

The error signal produced by error signal generator 40 is a pseudo-DC differential signal having an amplitude that is proportional to a duty cycle deviation from 50%. The output clock signal applied to terminals PIN and MIN causes the transistors Q1 and Q2 to control the integration of currents from current sources I1-I5 across capacitor C1 as a differential transconductor. The currents are switched from full positive to full negative by the output clock signal. When the output clock signal is negative, a net negative charge is driven onto the differential capacitor C1. When the output clock is positive, a net positive charge is driven onto the capacitor C1. If the Desired Duty Cycle Select signal is set to select a 50/50 duty cycle, a 50/50 output clock duty cycle will result in a zero volt differential error signal. Any deviation from a 50/50 output clock duty cycle under this condition will result in a net positive or negative charge across the capacitor C1. These characteristics of the error signal produced by error signal generator 40 are illustrated in FIG. 5.

The error signal produced by generator 40 is not a pure DC signal. It is a sawtooth waveform having a time-varying magnitude with the same frequency as the output clock signal (i.e., it is a pseudo-DC signal). These characteristics of the error signal are illustrated in FIG. 6 along with corresponding examples of a 70/30 duty cycle input clock signal (i.e., signal A in FIGS. 2 and 3) and a 50/50 duty cycle output clock signal (i.e., signal E in FIGS. 2 and 3).

FIG. 7 is a detailed schematic of one circuit implementation of the error signal generator 40 shown in FIGS. 2 and 4. Current source 14 is formed from transistors Q3-Q6 configured as a current mirror connected to both DAC D1 and transistor Q1. The positive duty cycle adjustment current selected by the Desired Duty Cycle Select signal is thereby mirrored into the differential integrator 41. Similarly, current source 15 is formed from transistors Q7-Q10 configured as a current mirror connected to DAC D2 and transistor Q2, and mirrors a negative duty cycle adjustment current selected by the Desired Duty Cycle select signal into the differential integrator 41. Current source 16 generates a static current reference that flows through transistor Q12 and resistor R7. Transistor Q12 and resistor R7, in combination with transistor Q13 and resistor R8, establish a reference bias voltage that is applied to transistors Q14-Q16. Transistors Q14, Q15, and Q16 in combination with resistors R9, R5, and R6 function as current sources. Transistors Q15-Q19 and resistors R1-R6 are configured as a common mode feedback loop 50 connected between the differential amplifier 41 and the output terminals PCORRECT and MCORRECT. The common mode feedback loop 50 sets the common mode voltage of the error signal to a specific level.

The amplitude of the error signal for a given frequency depends on the amplitude of the circuit currents in error signal generator 40 and the size of the integration. Reducing the amplitude of the sawtooth ripple of the error signal reduces the bandwidth of the loop. The ripple does not negatively affect the duty cycle correction function since the frequency of the ripple is the same as the frequency as the clock signal. As a result, the value of the output signal is always the same at a particular point in the clock period (after the loop has settled).

DACs D1 and D2 provide complementary currents which add an offset to the positive and negative charging currents applied to the integrating capacitor Cl. The charging offset results in a change to the clock duty cycle that satisfies the negative feedback loop. The duty cycle correction loop implemented by the circuit 10 will ideally stabilize at a duty cycle that gives a zero volt differential at the terminals PCORRECT and MCORRECT of the error signal generator 40. In this embodiment of the invention, the duty cycle correction function requires only a simple change to a DC current to make an adjustment.

A hypothetical control loop with infinite gain would settle when the error signal was at zero volts. However, actual control loops such as that of the duty cycle correction circuit 10 described herein have finite gain. A differential input signal greater than zero volts must therefore be applied to the duty cycle correctors 42 and 46 to generate a correction. The amount of the error signal applied to the duty cycle correctors 42 and 46 is equal to the difference between the actual and desired output signal duty cycles (in percent) divided by the gain of the duty cycle correction loop (in percent per volt).

FIG. 8 is a functional block diagram of the duty cycle corrector 42 shown in FIG. 2. The duty cycle corrector 42 includes a differential integrator 43 formed by transistors Q20 and Q21 and capacitor C2 connected to current sources 18-112 and diodes D11 and D12. Current sources 18 and 19 provide fixed and equal currents. Current sources I11 and I12 provide currents representative of the error signals received at the terminals PCORRECT and MCORRECT. Diodes DI1 and DI2 limit the differential output amplitude of the correction stage clock signal outputted by the duty cycle corrector 42 at terminals POUT and MOUT. Duty cycle corrector 46 can be identical to duty cycle corrector 42.

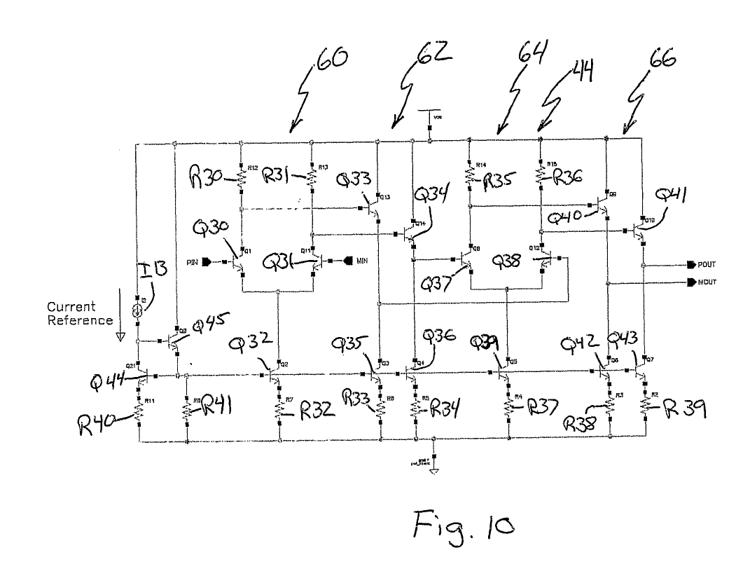

FIG. 9 is a detailed schematic of one circuit implementation of the duty cycle corrector 42 shown in FIGS. 2 and 7. The function of capacitor C2 can be provided by parasitic capacitance. Diodes DI1 and DI2 are formed by transistors Q22 and Q23 connected as diodes. The output amplitude limitation provided by diodes DI1 and DI2 allows the duty cycle corrector 42 to operate over a wide range of frequencies and manufacturing process variations without the need to trim or calibrate the bias currents. The bias currents are effectively selected by the Frequency Select signal applied to DAC D3. In response to the Frequency Select signal, DAC D3 establishes a reference current that flows through transistor Q24 and resistor R10. Transistor Q24 and resistor R10, in combination with transistor Q25 and resistor R11, establish a reference bias voltage that is applied to transistors Q26-Q28. The transistors Q26-Q28, in combination with resistors R12-R14, function as the current sources I10-I12 shown in FIG. 8. The reference current selected though operation of DAC D3 scales linearly with the clock signal frequency to keep the rise and fall times of the clock signal (measured as a percentage of the clock period), and therefore the gain of the correction loop of duty cycle correction circuit 10, constant with the clock signal frequency. Absent such a scaling function the edge rates of the clock signals can become a larger portion of the clock period as the frequency increases, resulting in increased loop gain.

The duty cycle adjustment functionality is provided by transistors Q29 and Q30 and resistor R15 in combination with the circuit elements that form current sources I11 and I12. Transistors Q27-Q30 and resistors R13-R15 are configured to function as a linearized differential amplifier 54 that is connected to the differential integrator 43. Differential amplifier 54 sinks an amount of current proportional to the error signal from the output terminals POUT and MOUT to ground. The rate of charge accumulation on capacitor C2, and therefore the slope of the clock signal edges, is thereby controlled by the error signal. The amount of duty cycle correction is linearly proportional to the error signal since the differential amplifier 54 provides a linear voltage to correction current conversion.

FIG. 10 is a detailed schematic of one circuit implementation of the buffer 44 shown in FIG. 2. Buffer 48 can be identical to buffer 44. Buffer 44 is a two stage circuit in the illustrated embodiment, and includes a first differential amplifier 60, first buffers 62, second differential amplifier 64 and second buffers 66. First differential amplifier 60, which is formed from transistors Q30-Q32 and resistors R30-R32, is connected to receive the clock signal at terminals PIN and MIN. Buffers 62 are formed from transistors Q33-Q36 and resistors R33 and R34. Transistors Q33 and Q34 are configured as emitter followers, and are connected to receive the amplified clock signal outputted from differential amplifier 60. Second differential amplifier 64 is formed from transistors Q37-Q39 and resistors R35-R37 and is connected to receive the buffered clock signal outputted from buffers 62. Second buffers 66 are formed from transistors Q40-Q43 and resistors R38 and R39. Transistors Q40 and Q41 are configured as emitter followers, and are connected to receive the amplified clock signal outputted from differential amplifier 64. The output of buffers 66 are connected to output terminals POUT and MOUT. Current source I13 generates a reference current that flows through transistor Q44 and resistor R40. Transistor Q44 and resistor R40, in combination with transistor Q45 and resistor R41, establish a reference bias voltage that is applied to transistors Q32, Q35, Q36, Q39, Q42 and Q43, all of which function as current sources. Differential amplifiers 60 and 64 are high gain amplifiers that convert the relatively slow edges of the clock signals received at their inputs to relatively sharp and symmetrical edges.

The invention offers a number of important advantages. The negative feedback loop configuration provides self correction of the clock signal duty cycle. The duty cycle can be selected to have values other than 50%. A wide range of clock signal frequencies can be accommodated. The circuit can also be efficiently implemented.

Although the present invention has been described with reference to preferred embodiments, those skilled in the art will recognize that changes can be made in form and detail without departing from the spirit and scope of the invention. This application claims the benefit of U.S. Provisional Application Ser. No. 60/643,926, filed Jan. 14, 2005, and entitled Clock Circuit, which is incorporated herein in its entirety.

What is claimed is:

1. A clock pulse duty cycle control circuit for receiving an input clock signal and for providing an output clock signal having a desired duty cycle, including:
an error signal generator connected to receive the output clock signal, for producing an error signal representative of a difference between the output clock signal duty cycle and a desired duty cycle;
a first duty cycle corrector connected to receive the error signal and an input clock signal, for adjusting slopes of the input clock signal edges as a function of the error signal and producing a first correction stage clock signal; and
a first buffer connected to receive the first correction stage clock signal, for squaring the edges of the clock signal to produce the output clock signal.

2. The clock pulse duty cycle control circuit of claim 1 wherein the error signal generator includes an integrator for integrating the output clock signal to produce a time-varying DC error signal representative of a difference between the output clock signal duty cycle and the desired duty cycle.

3. The clock pulse duty cycle control circuit of claim 2 wherein the error signal generator includes an integrator for integrating the output clock signal to produce a time-varying DC error signal, at the frequency of the output clock signal, representative of a difference between the output clock signal duty cycle and the desired duty cycle.

4. The clock pulse duty cycle control circuit of claim 3 wherein the error signal generator includes an integrator for integrating the output clock signal and producing a time-varying DC error signal, at the frequency of the output clock signal, having a magnitude representative of a difference between the output clock signal duty cycle and the desired duty cycle.

5. The clock pulse duty cycle control circuit of claim 1 and further including a duty cycle selector connected to the error signal generator for selecting the desired clock signal duty cycle.

6. The clock pulse duty cycle control circuit of claim 5 wherein the duty cycle selector includes a digital input for receiving a digital control signal representative of the desired clock signal duty cycle.

7. The clock pulse duty cycle control circuit of claim 1 wherein the error signal generator includes:
an integrator for integrating the output clock signal to produce a time-varying DC error signal representative of a difference between the output clock signal duty cycle and the desired duty cycle; and
a duty cycle selector connected to the integrator for selecting the desired clock signal duty cycle.

8. The clock pulse duty cycle control circuit of claim 7 wherein the duty cycle selector includes a current source connected to the integrator and having a digital input, for receiving a digital control signal representative of the desired clock signal duty cycle and for producing a duty cycle adjustment current as a function of the control signal.

9. The clock pulse duty cycle control circuit of claim 1 wherein the error signal generator farther includes a common mode feedback loop connected to the integrator, for setting the common mode voltage of the error signal.

10. The clock pulse duty cycle control circuit of claim 1 wherein the first duty cycle corrector includes:
an integrator for integrating the input clock signal; and
a duty cycle adjustor connected to receive the error signal and connected to the integrator, for controlling the integrator.

11. The clock pulse duty cycle control circuit of claim 10 wherein the integrator includes signal level-limiting diodes.

12. The clock pulse duty cycle control circuit of claim 10 and further including a frequency selector connected to the integrator for compensating for the frequency of the clock signal.

13. The clock pulse duty cycle control circuit of claim 12 wherein the frequency selector has a digital input for receiving a digital control signal representative of the frequency of the clock signal.

14. The clock pulse duty cycle control circuit of claim 1 wherein the buffer includes a high gain amplifier.

15. The clock pulse duty cycle control circuit of claim 1 and further including:
a second duty cycle corrector connected to receive the error signal and an input clock signal, for adjusting slopes of the input clock signal edges as a function of the error signal and producing a second correction stage clock signal; and
a second buffer connected between the second duty cycle corrector and the first duty cycle corrector, for receiving the second correction stage clock signal and for squaring the edges of the clock signal to produce the input clock signal to the first duty cycle corrector.

16. A clock pulse duty cycle control circuit for receiving an input clock signal and for providing an output clock signal having a desired duty cycle, including:
a first error signal generator, including:
a differential integrator connected to receive the output clock signal, for integrating the output clock signal and producing a time-varying DC error signal, at the frequency of the output clock signal, having a magnitude representative of a difference between the output clock signal duty cycle and a desired duty cycle; and
a differential common mode feedback loop connected to the integrator, for setting the common mode voltage of the error signal;
a first duty cycle corrector, including:
a differential integrator connected to receive an input clock signal, for integrating the input clock signal and producing a first correction stage clock signal; and
a differential duty cycle adjustor connected to the differential integrator and to the error signal generator, for causing the integrator to adjust slopes of the input clock signal edges as a function of the error signal; and
a first buffer connected to receive the first correction stage clock signal, for squaring the edges of the clock signal to produce the output clock signal.

17. The clock pulse duty cycle control circuit of claim 16 wherein the error signal generator further includes a duty cycle selector comprising current sources connected to the differential integrator and having a digital input, for receiving a digital control signal representative of the desired clock signal duty cycle and for producing duty cycle adjustment currents as a function of the control signal.

18. The clock pulse duty cycle control circuit of claim 17 wherein the duty cycle corrector further includes a frequency selector connected to the differential integrator and to the differential common mode feedback loop and having a digital input, for receiving a digital control signal representative of the clock signal frequency and for compensating for the frequency of the clock signal.

19. The clock pulse duty cycle control circuit of claim 16 and further including:
a second duty cycle corrector connected to receive the error signal and an input clock signal, for adjusting slopes of the input clock signal edges as a function of the error signal and producing a second correction stage clock signal; and
a second buffer connected between the second duty cycle corrector and the first duty cycle corrector, for receiving the second correction stage clock signal and for squaring the edges of the clock signal to produce the input clock signal to the first duty cycle corrector.
